(19) United States
(12) Patent Application Publication
(10) Pub. No.: US 2021/0354425 A1
(43) Pub. Date: Nov. 18, 2021

(54) SEALANT STRUCTURE AND METHOD OF FABRICATING DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventor: Mingjun Zhou, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/617,934

(22) PCT Filed: Nov. 4, 2019
(86) PCT No.: PCT/CN2019/115371

§ 371 Date: Nov. 27, 2019

(30) Foreign Application Priority Data
Jul. 19, 2019 (CN) 201910654950.9

(51) Int. Cl. B32B 7/14; B32B 37/12; B32B 37/00; C09J 5/06

(52) U.S. Cl. CPC B32B 7/14; B32B 37/1292; B32B 2457/20; C09J 5/06; B32B 2037/1215; B32B 37/0076

(57) ABSTRACT

A sealant structure and a method of fabricating a display panel are provided. The sealant structure comprising a first adhesive layer and a second adhesive layer, wherein the first adhesive layer comprises a plurality of first adhesive strips, the first adhesive strips are adjacent to each other end to end, and a first gap is disposed between any two adjacent first adhesive strips; wherein the second adhesive layer comprises a plurality of second adhesive strips, the second adhesive strips are adjacent to each other end to end, and a second gap is disposed between any two adjacent second adhesive strips; wherein projections of first gaps on a display body do not overlap with projections of second gaps on a display body.

### BACKGROUND OF INVENTION

### Field of Invention

The present invention relates to the field of electronic display, and in particular, to a sealant and a method of fabricating a display panel.

### Description of Prior Art

In the prior art, a body and a cover glass of a display panel are usually bonded by thermoplastic glues, which are flexible solids at room temperature and have a low viscosity. Adhesive strips of thermoplastic glues can be melted after being heated and solidified to a high viscosity solid after the temperature is lowered. In the prior art, for a display panel having a rectangular structure, in order to save cost, the adhesive strips for bonding display panel are usually formed by four spliced adhesive strips. As frame width of the display panels is gradually reduced, width of the adhesive strips is also reduced, therefore higher requirements are imposed on splicing precision of the adhesive strips.

### Technical Problems

Referring to FIG. 1, if gaps between the adhesive strips are too large, the melted adhesive strips would not be able to fill the gaps, which may result in the display panel being unsealed. If an area of the overlapping adhesive strips is too large during splicing, the adhesive strips in the overlap area would be too thick to melt completely and form a splicing gap, which may also result in the display panel being unsealed.

### SUMMARY OF INVENTION

In order to solve the above problems, the present application provides a sealant structure and a method of fabricating a display panel to solve the technical problem that the display body and the cover plate cannot be sealed.

The application provides a sealant structure comprising a first adhesive layer and a second adhesive layer,

wherein the first adhesive layer comprises a plurality of first adhesive strips, the first adhesive strips are adjacent to each other end to end, and a first gap is disposed between any two adjacent first adhesive strips;

wherein the second adhesive layer comprises a plurality of second adhesive strips, the second adhesive strips are adjacent to each other end to end, and a second gap is disposed between any two adjacent second adhesive strips;

wherein projections of the first gaps on a display body separates from projections of the second gaps on the display body.

According to one aspect of the application, wherein the first adhesive strips and the second adhesive strips have a same width.

According to one aspect of the application, wherein the first adhesive strips and the second adhesive strips have a same thickness.

According to one aspect of the application, wherein a width of the first gaps and a width of the second gaps are less than or equal to twice the width of the first and second adhesive strips.

According to one aspect of the application, wherein the first adhesive strips and the second adhesive strips are formed of a same material.

According to one aspect of the application, wherein a material forming the first adhesive strips and the second adhesive strips is a thermoplastic adhesive.

According to one aspect of the application, wherein the thermoplastic adhesive comprises a combination of one or more of polyvinyl acetate, polyvinyl acetal, ethylene-vinyl acetate copolymer resin, vinyl chloride-vinyl acetate copolymer resin, and perchlorination. Vinyl, polyacrylate, polyamide and polysulfone.

According to one aspect of the application, wherein the sealant structure is rectangular, the first adhesive strips constituting the first adhesive layer comprises a first sub-adhesive strip, a second sub-adhesive strip, and a third sub-adhesive strip and fourth sub-adhesive strip, four first gaps are disposed between the first sub-adhesive strip, the second sub-adhesive strip, the third sub-adhesive strip and the fourth sub-adhesive strip;

wherein the second adhesive strips constituting the second adhesive layer comprises a fifth sub-adhesive strip, a sixth sub-adhesive strip, a seventh sub-adhesive strip and an eighth sub-adhesive strip, four second gaps are disposed between the fifth sub-adhesive strip, the sixth sub-adhesive strip, the seventh sub-adhesive strip and the eighth sub-adhesive strip.

According to one aspect of the application, wherein the fifth sub-adhesive strip, the sixth sub-adhesive strip, the seventh sub-adhesive strip and the eighth sub-adhesive strip cover the four first gaps, the four second gaps are disposed above the first sub-adhesive strip, the second sub-adhesive strip, the third sub-adhesive strip and the fourth sub-adhesive strip.

The present application further provides a method of fabricating a display panel, wherein the method comprises the steps of:

providing a display body comprising a display area and a non-display area surrounding the display area;

providing a first adhesive layer on the non-display area, wherein the first adhesive strips are adjacent to each other end to end, and a first gap is disposed between any two adjacent first adhesive strips;

providing a second adhesive layer on the first adhesive layer, wherein the second adhesive layer comprises a plurality of second adhesive strips, the second adhesive strips are adjacent to each other end to end, and a second gap is disposed between any two adjacent second adhesive strips, projections of the first gaps on a display body separates from projections of the second gaps on the display body.

heating the first adhesive layer and the second adhesive layer, causing the first adhesive layer and the second adhesive layer to melt and deform to form an adhesive unit;

cooling and curing the adhesive unit to form a sealed space by a cover plate and the display body.

### Beneficial Effects

The present application adopts an adhesive unit consisting of a first adhesive layer and a second adhesive layer. The first adhesive layer includes a plurality of first adhesive strips, the first adhesive strips are adjacent to each other end to end, and a first gap is disposed between any two adjacent first adhesive strips. The second adhesive layer includes a plurality of second adhesive strips, the second adhesive strips are adjacent to each other end to end, and a second gap is disposed between any two adjacent second adhesive strips. Projections of the first gaps on a display body do not overlap with projections of the second gaps on the display body. In this arrangement, the overlapping area of two adjacent adhesive strips is eliminated, thereby preventing incomplete melting generated by uneven heating. At the same time, a length of the overlap region is much larger than a width of a strip and the tolerance range is large, therefore, the requirement of alignment precision of the adhesive strips is low, which is convenient for pasting. The technical solution of the present application can optimize the sealing effect of the display panel without increasing the difficulty of the process.

### BRIEF DESCRIPTION OF DRAWINGS

FIG. 1 is a structural diagram of a display body and a sealant structure in the prior art.

FIG. 2 is a cross-sectional view taken along a direction of AA1 in FIG. 1.

FIG. 3 is a cross-sectional view of a display panel after adhesive strips in FIG. 2 are fused.

FIG. 4 is a cross-sectional view taken along a direction of BB 1 of FIG. 1.

FIG. 5 is a cross-sectional view of a display panel after adhesive strips in FIG. 4 are fused.

FIG. 6 is a structural diagram of a display panel and a first adhesive layer in an embodiment of the present application.

FIG. 7 is a cross-sectional view taken along a direction of CC1 of FIG. 6.

FIG. 8 is a cross-sectional view taken along a direction of DD1 of FIG. 6.

FIG. 9 is a structural diagram of a display panel and a second adhesive layer in an embodiment of the present application.

FIG. 10 is a cross-sectional view taken along a direction of CC1 of FIG. 9.

FIG. 11 is a cross-sectional view taken along a direction of DD1 of FIG. 9.

FIG. 12 is a cross-sectional view of the adhesive strips of FIG. 10 after melting.

FIG. 13 is a cross-sectional view of the adhesive strips of FIG. 11 after melting.

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

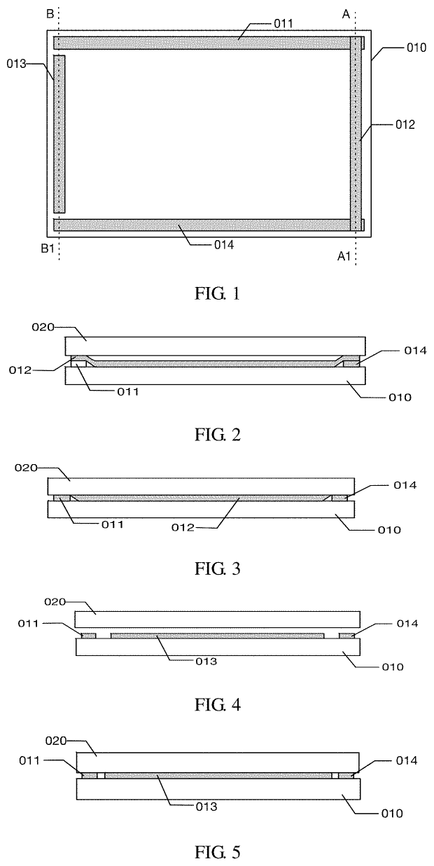

First, the prior art will be briefly described. Referring to FIG. 1, a display panel includes a substrate 010 and a first adhesive strip 011, a second adhesive strip 012, a third adhesive strip 013, and a fourth adhesive strip 014 on the substrate 010. The first adhesive strip 011, the second adhesive strip 012, the third adhesive strip 013, and the fourth adhesive strip 014 are disposed around edges of the substrate 010.

In the prior art, the adhesive strips are thermoplastic glues, which are flexible solids at room temperature and have a low viscosity. Adhesive strips of thermoplastic glues can be melted after being heated and solidified to a high viscosity solid after the temperature is lowered. Because the adhesive strips are soft and susceptible to deformation during splicing, when pasted onto the substrate 010, lengths of the adhesive strips are easily changed by an external force, thereby generating gaps or overlapping between adjacent adhesive strips.

Referring to FIG. 2, the second adhesive strip 012 overlaps with the adjacent first adhesive strip 011 and the fourth adhesive strip 014. Widths of overlapping regions are equal to widths of the first adhesive strip 011 and the fourth adhesive strip 014. When bonding with a cover plate 020, thicknesses of the overlapping regions are too thick, resulting in uneven heat distribution of the adhesive strips. The adhesive strips near the overlapping regions cannot be melted, forming an air passage between adjacent adhesive strips, as shown in FIG. 3.

Referring to FIG. 4, large gaps exist between the third adhesive strip 013 and the first adhesive strip 011 and the fourth adhesive strip 014 adjacent to the third adhesive strip 013. Because widths of the gaps are too large, the melted adhesive strips cannot completely fill the gaps, resulting in an air passage between adjacent adhesive strips, as shown in FIG. 5.

In order to solve the above problems, the present application provides a sealant structure and a method of fabricating a display panel to solve the technical problem that the display body and the cover plate cannot be sealed.

Referring to FIG. 13, the present application provides the sealant structure for bonding the display body 10 and the cover plate 20.

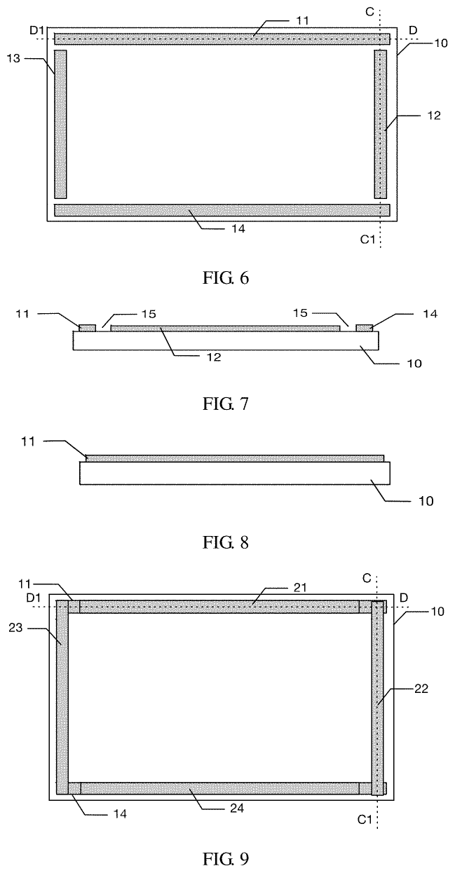

Referring to FIG. 6 to FIG. 8, FIG. 6 is a structural diagram of a display panel and a first adhesive layer in an embodiment of the present application. FIG. 7 is a cross-sectional view taken along a direction of CC1 of FIG. 6. FIG. 8 is a cross-sectional view taken along a direction of DD1 of FIG. 6.

The display body 10 includes a display area and a non-display area surrounding the display area, the adhesive unit is disposed on the non-display area, and the adhesive unit includes a first adhesive layer and a second adhesive layer. The cover plate 20 is attached to the display body 10 by the adhesive unit, and forms a sealed space with the display body 10.

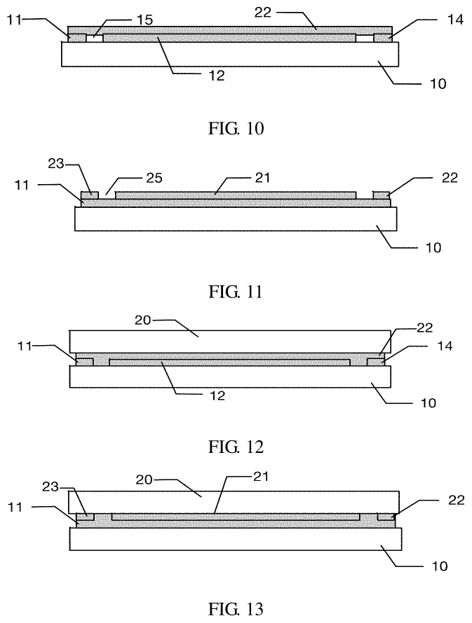

Referring to FIG. 9 to FIG. 11, FIG. 9 is a structural diagram of a display panel and a second adhesive layer in an embodiment of the present application. FIG. 10 is a cross-sectional view taken along a direction of CC1 of FIG. 9. FIG. 11 is a cross-sectional view taken along a direction of DD1 of FIG. 9. The first adhesive layer comprises a plurality of first adhesive strips, the first adhesive strips are adjacent to each other end to end, and a first gap 15 is disposed between any two adjacent first adhesive strips. The second adhesive layer comprises a plurality of second adhesive strips, the second adhesive strips are adjacent to each other end to end, and a second gap 25 is disposed between any two adjacent second adhesive strips. Wherein, projections of the first gaps 15 on a display body do not overlap with projections of the second gaps 25 on the display body.

The present application provides a gap between adjacent strips to prevent overlapping of adjacent adhesive strips. Because the overlapping area is eliminated, the present application can prevent an air passage formed in the prior art due to uneven melting of the adhesive strips. Meanwhile, the present application provides an adhesive unit consisting of a first adhesive layer and a second adhesive layer. Projections of the first gaps 15 on a display body do not overlap with projections of the second gaps 25 on the display body. When the first adhesive layer and the second adhesive layer are heated subsequently, the adhesive strips are heated and melted. The first adhesive strips in the first adhesive layer fills the second gaps 25 in the second adhesive layer. At the same time, the second adhesive strips in the second adhesive layer fills the first gaps 15 in the first adhesive layer. This creates a closed loop that eliminates the air passage.

In the present application, in order to simplify the process difficulty while ensuring that the first gaps 15 and the second gaps 25 are completely filled, the plurality of first adhesive strips and the plurality of second adhesive strips have a same width and a same thickness. At the same time, in order to prevent insufficient filling due to the first gaps 15 and the second gaps 25 being too wide, a width of the first gaps 15 and a width of the second gaps 25 are less than or equal to twice the width of the first and second adhesive strips.

In the present application, a same material forming the first adhesive strips and the second adhesive strips is a thermoplastic adhesive, the thermoplastic adhesive is selected from a combination of one or more of polyvinyl acetate, polyvinyl acetal, ethylene-vinyl acetate copolymer resin, vinyl chloride-vinyl acetate copolymer resin, perchloroethylene resin, polyacrylate, polyamide, and polysulfone.

In this embodiment, a rectangular sealant structure is taken as an example for description. Correspondingly, a number of the adhesive strips is four. It should be noted that the shape of the sealant structure and the number of adhesive strips in the present embodiment are only for explaining the present invention and are not to be construed as limiting the present invention.

Referring to FIG. 6, the sealant structure is rectangular, the first adhesive strips constituting the first adhesive layer comprise a first sub-adhesive strip 11, a second sub-adhesive strip 12, a third sub-adhesive strip 13, and a fourth sub-adhesive strip 14. Four first gaps 15 are disposed between the first sub-adhesive strip 11, the second sub-adhesive strip 12, the third sub-adhesive strip 13, and the fourth sub-adhesive strip 14. Referring to FIG. 9, the second adhesive strips constituting the second adhesive layer comprise a fifth sub-adhesive strip 21, a sixth sub-adhesive strip 22, a seventh sub-adhesive strip 23, and an eighth sub-adhesive strip 24. Four second gaps 25 are disposed between the fifth sub-adhesive strip 21, the sixth sub-adhesive strip 22, the seventh sub-adhesive strip 23, and the eighth sub-adhesive strip 24. The fifth sub-adhesive strip 21, the sixth sub-adhesive strip 22, the seventh sub-adhesive strip 23, and the eighth sub-adhesive strip 24 cover the four first gaps 15. The four second gaps 25 are disposed above the first sub-adhesive strip 11, the second sub-adhesive strip 12, the third sub-adhesive strip 13, and the fourth sub-adhesive strip 14.

Correspondingly, the present application also provides a method for fabricating a sealant structure, the method comprising the following steps.

First, a display body 10 is provided, which includes a display area and a non-display area surrounding the display area.

Thereafter, referring to FIG. 6, a first adhesive layer is disposed on the non-display area, wherein the first adhesive layer comprises a plurality of first adhesive strips, the first adhesive strips are adjacent to each other end to end, and a first gap 15 is disposed between any two adjacent first adhesive strips.

Thereafter, referring to FIG. 9, providing a second adhesive layer on the first adhesive layer, wherein the second adhesive layer comprises a plurality of second adhesive strips, the second adhesive strips are adjacent to each other end to end, and a second gap 25 is disposed between any two adjacent second adhesive strips. Projections of the first gaps 15 on the display body 10 do not overlap with projections of the second gaps 25 on the display body 10.

In the present embodiment, the sealant structure is rectangular, the first adhesive strips constituting the first adhesive layer comprise a first sub-adhesive strip 11, a second sub-adhesive strip 12, a third sub-adhesive strip 13, and a fourth sub-adhesive strip 14. Four first gaps 15 are disposed between the first sub-adhesive strip 11, the second sub-adhesive strip 12, the third sub-adhesive strip 13, and the fourth sub-adhesive strip 14. Referring to FIG. 9, the second adhesive strips constituting the second adhesive layer comprise a fifth sub-adhesive strip 21, a sixth sub-adhesive strip 22, a seventh sub-adhesive strip 23, and an eighth sub-adhesive strip 24. Four second gaps 25 are disposed between the fifth sub-adhesive strip 21, the sixth sub-adhesive strip 22, the seventh sub-adhesive strip 23, and the eighth sub-adhesive strip 24. The fifth sub-adhesive strip 21, the sixth sub-adhesive strip 22, the seventh sub-adhesive strip 23, and the eighth sub-adhesive strip 24 cover the four first gaps 15, and the four second gaps 25 are disposed above the first sub-adhesive strip 11, the second sub-adhesive strip 12, the third sub-adhesive strip 13, and the fourth sub-adhesive strip 14.

Finally, referring to FIG. 12 and FIG.13, heating the first adhesive layer and the second adhesive layer, causing the first adhesive layer and the second adhesive layer to melt and deform to form an adhesive unit. Cooling and curing the adhesive unit, so that a sealed space is formed by a cover plate 20 and the display body 10.

The present application provides a gap between adjacent strips to prevent overlapping of adjacent adhesive strips. Because the overlapping area is eliminated, the present application can prevent an air passage formed in the prior art due to uneven melting of the adhesive strips. Meanwhile, the present application provides an adhesive unit consisted of a first adhesive layer and a second adhesive layer. Projections of the first gaps 15 on a display body do not overlap with projections of the second gaps 25 on the display body. When the first adhesive layer and the second adhesive layer are heated subsequently, the adhesive strips are heated and melted. The first adhesive strips in the first adhesive layer fills the second gaps 25 in the second adhesive layer. At the same time, the second adhesive strips in the second adhesive layer fills the first gaps 15 in the first adhesive layer. This creates a closed loop that eliminates the air passage.

The present application adopts an adhesive unit consisting of a first adhesive layer and a second adhesive layer. The first adhesive layer includes a plurality of first adhesive strips, the first adhesive strips are adjacent to each other end to end, and a first gap is disposed between any two adjacent first adhesive strips. The second adhesive layer includes a plurality of second adhesive strips, the second adhesive strips are adjacent to each other end to end, and a second gap is disposed between any two adjacent second adhesive strips. Projections of the first gaps on a display body do not overlap with projections of the second gaps on the display body. In this arrangement, the overlapping area of two adjacent adhesive strips is eliminated, thereby preventing incomplete melting generated by uneven heating. At the same time, a length of the overlap region is much larger than a width of a strip and the tolerance range is large, therefore, the requirement of alignment precision of the adhesive strips is low, which is convenient for pasting. The technical solution of the present application can optimize the sealing effect of the display panel without increasing the difficulty of the process.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

What is claimed is:

1. A sealant structure comprising a first adhesive layer and a second adhesive layer;
wherein the first adhesive layer comprises a plurality of first adhesive strips, the first adhesive strips are adjacent to each other end to end, and a first gap is disposed between any two adjacent first adhesive strips;
wherein the second adhesive layer comprises a plurality of second adhesive strips, the second adhesive strips are adjacent to each other end to end, and a second gap is disposed between any two adjacent second adhesive strips; and
wherein projections of a plurality of first gaps on a display body do not overlap with projections of a plurality of second gaps on the display body.

2. The sealant structure according to claim 1, wherein the first adhesive strips and the second adhesive strips have a same width.

3. The sealant structure according to claim 1, wherein the first adhesive strips and the second adhesive strips have a same thickness.

4. The sealant structure according to claim 2, wherein a width of the first gaps and a width of the second gaps are less than or equal to twice the width of the first and second adhesive strips.

5. The sealant structure according to claim 1, wherein the first adhesive strips and the second adhesive strips are formed of a same material.

6. The sealant structure according to claim 5, wherein the material forming the first adhesive strips and the second adhesive strips is a thermoplastic adhesive.

7. The sealant structure according to claim 6, wherein the thermoplastic adhesive comprises a combination of one or more of polyvinyl acetate, polyvinyl acetal, ethylene-vinyl acetate copolymer resin, vinyl chloride-vinyl acetate copolymer resin, perchloroethylene resin, polyacrylate, polyamide, and polysulfone.

8. The sealant structure according to claim 1, wherein the sealant structure is rectangular, the first adhesive strips constituting the first adhesive layer comprise a first sub-adhesive strip, a second sub-adhesive strip, a third sub-adhesive strip, and a fourth sub-adhesive strip, and four first gaps are disposed between the first sub-adhesive strip, the second sub-adhesive strip, the third sub-adhesive strip, and the fourth sub-adhesive strip; and
wherein the second adhesive strips constituting the second adhesive layer comprise a fifth sub-adhesive strip, a sixth sub-adhesive strip, a seventh sub-adhesive strip, and an eighth sub-adhesive strip, and four second gaps are disposed between the fifth sub-adhesive strip, the sixth sub-adhesive strip, the seventh sub-adhesive strip, and the eighth sub-adhesive strip.

9. The sealant structure according to claim 8, wherein the fifth sub-adhesive strip, the sixth sub-adhesive strip, the seventh sub-adhesive strip, and the eighth sub-adhesive strip cover the four first gaps, and the four second gaps are disposed above the first sub-adhesive strip, the second sub-adhesive strip, the third sub-adhesive strip, and the fourth sub-adhesive strip.

10. A method of fabricating a display panel, wherein the method comprises steps of:
providing a display body comprising a display area and a non-display area surrounding the display area;
providing a first adhesive layer on the non-display area, wherein the first adhesive layer comprises a plurality of first adhesive strips, the first adhesive strips are adjacent to each other end to end, and a first gap is disposed between any two adjacent first adhesive strips;
providing a second adhesive layer on the first adhesive layer, wherein the second adhesive layer comprises a plurality of second adhesive strips, the second adhesive strips are adjacent to each other end to end, and a second gap is disposed between any two adjacent second adhesive strips, and projections of a plurality of first gaps on the display body do not overlap with projections of a plurality of second gaps on the display body;
heating the first adhesive layer and the second adhesive layer, causing the first adhesive layer and the second adhesive layer to melt and deform to form an adhesive unit; and
cooling and curing the adhesive unit, so that a sealed space is formed by a cover plate and the display body.
